(19) United States
(12) Patent Application Publication
(10) Pub. No.: US 2003/0181055 A1
(43) Pub. Date: Sep. 25, 2003

(54) Method of removing photo-resist and polymer residue

(76) Inventors: Ching-Ping Wu, Taipei (TW); H. W. Lee, Feng-Shan City (TW); Tung-Yuan Hou, Taitung City (TW); Yen-Huei Su, Shioushuei Shiang (TW); Nan-Tzu Lian, Hsinchu (TW); Hsin-Cheng Liu, Hsinchu (TW)

Correspondence Address: RABIN & CHAMPAGNE, PC, 1101 14TH STREET, NW, SUITE 500, WASHINGTON, DC, 20005, US

(21) Appl. No.: 10/359,297

(22) Filed: Feb. 6, 2003

(30) Foreign Application Priority Data
Feb. 8, 2002 (TW) 091102315

(51) Int. Cl. H01L 21/302; H01L 21/461

(52) U.S. Cl. 438/709; 438/710

(57) ABSTRACT

A method of removing sidewall polymer fence of the dielectric layer, which is a wet strip process using acidic SC1 and CR solutions, and SC1 solution is applied before CR solution. SC1 solution substantially comprises ammonium hydroxide, sulfuric acid and water for removing sidewall polymer fence, and CR solution substantially comprises sulfuric acid and hydrogen peroxide for removing photo-resist. The key of the wet strip process of the invention is that SC1 solution is applied at a low temperature for reducing the oxide loss. The wet strip process of the invention can completely remove the sidewall polymer fence and reduce the oxide loss of the dielectric layer.

This application claims the benefit of Taiwan application Serial No. 91102315, filed Feb. 08, 2002.

### BACKGROUND OF THE INVENTION

1. Field of the Invention

The invention relates in general to a method of removing photo-resist and the polymer residue, and more particularly to the method of removing sidewall polymer fence without damaging a to-be-patterned layer, such as a dielectric layer.

2. Description of the Related Art

In the manufacturing process of semiconductor devices, photo-resist (PR) is typically applied as a mask for patterning. After the desired patterning of the layers beneath the photo-resist layer is completed, one of the important steps thereafter is to completely remove the PR mask.

Recently, a dry etching process, using plasma-etching gas, is mostly adapted to pattern conductive layers. The dry etching process possesses the advantages of easily being controlled and producing a sharp pattern, but the drawback is that the dry etching process makes photo-resist cross-linked and hardened, so that the removal of the photo-resist becomes difficult. To remove stubborn photo-resist, a more aggressive stripper needs to be chosen. However, a strong stripper could be harmful and damage to the semiconductor devices, by causing problems such as electrically properties shift. For some of semiconductor device, flash memory especially, the stripper must be carefully selected to avoid the damage.

If the photo-resist residue is remained, further problems could occur. For example, after the etching process, a polymer layer is frequently formed on the sidewall of the via contact hole, consequently named the sidewall polymer fence. The sidewall polymer fence causes the dramatic flaws of the semiconductor device, such as vias with higher resistance. Accordingly, the sidewall polymer fence must be removed completely.

In the following paragraphs, the flash memory is taken for illustration, and a conventional method of removing the photo-resist and the sidewall polymer fence of the flash memory is described with reference to FIGS. 1˜FIGS. 3.

FIG. 1 is the sectional drawing of a flash memory substrate on which a dielectric layer and a patterned PR have been formed. The dielectric layer 102, comprising a bottom oxide (tunnel oxide) layer 104, a silicon nitride (SIN) layer 106, and a top oxide layer 108, is deposited over the substrate 100. A photo-resist (PR) layer is further deposited over the dielectric layer 102, and then developed to form the patterned PR 110.

FIG. 2 is the flash memory of FIG. 1 following a pattern etching process. The dielectric layer 102 deposited over the substrate 100 is etched in accordance with the patterned PR 110. It is assumed that the etching is controlled to stop on the top of the bottom oxide layer 104 thereby forms a via contact hole 114. After pattern etching process, a sidewall polymer fence 112 is commonly formed on the sidewall of the patterned photo-resist 110 and the via contact hole 114 by the reaction of photo-resist and the dielectric layer 102.

FIG. 3 is the flash memory of FIG. 2 after removing photo-resist and the sidewall polymer fence by a conventional method. Conventionally, the PR 110 (FIG. 2) is removed by a dry strip method using an oxygen (O2) plasma, and the sidewall polymer fence 112 is subsequently removed by a chemical acidic solution. A common acidic solution is named CR solution, which substantially comprises sulfuric acid (H2SO4) and hydrogen peroxide (H2O2). However, the dry etch performed in step of removing PR has made the sidewall polymer fence 112 hardened and difficult to be removed. Therefore, the polymer residue 116 still remains on the sidewall after stripped by CR solution, as shown in FIG. 3. Also, since the PR 110 has been removed, the bare top oxide 108 may be attacked by acidic CR solution and causes the electrical properties shift of the flash memory. Additionally, in order to completely removing the sidewall polymer fence 112, a more aggressive stripper may be selected and applied herein. The following drawback is the occurrence of considerably loss of the top oxide 108.

According to the description above, it is the main concern for the manufacturers that how to effectively remove the PR and the sidewall fence polymer without causing any damage to the semiconductor device.

### SUMMARY OF THE INVENTION

It is therefore an object of the invention to provide a method of removing photo-resist and the polymer residue, so that the polymer residue, such as the sidewall polymer fence, is efficiently removed and attack of the dielectric layer (ONO layer) is reduced.

The invention achieves the above-identified objects by providing a method of removing photo-resist and the polymer residue, wherein the polymer residue is undesired formed while a photo-resist mask is used to pattern at least a layer there beneath, and the method comprises the steps of: (a) applying SC1 solution, which substantially comprises ammonium hydroxide, sulfuric acid and water, at a temperature ranged from about 30□ to 40□; and (b) applying CR solution, which substantially comprises sulfuric acid and hydrogen peroxide.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 is the sectional drawing of a flash memory substrate on which a dielectric layer and a patterned PR have been formed;

FIG. 2 is the flash memory of FIG. 1 following a pattern etching process;

FIG. 3 (prior art) is the flash memory of FIG. 2 after removing photo-resist and the sidewall polymer fence by a conventional method; and

FIG. 4 is the flash memory of FIG. 2 after removing photo-resist and the sidewall polymer fence according to the preferred strip process of the invention.

### DETAILED DESCRIPTION OF THE INVENTION

In the following description, the flash memory is taken as an example for illustrating the process of removing photo-resist (PR) and the sidewall fence polymer after a via contact hole is etched. However, it is apparent that the process of the invention is not limited hereto but can be applied in other semiconductor devices. Also, to avoid obscuring the invention, well-known elements not directly relevant to the invention are not shown or described. Accordingly, the specification and the drawing are to be regard as an illustrative sense rather than a restrictive sense.

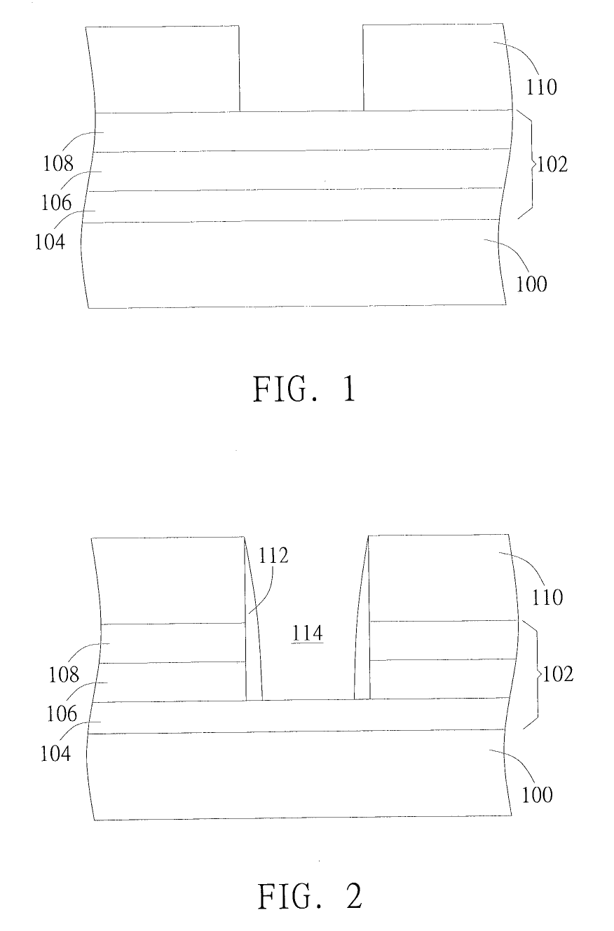

The etching process for patterning a via contact hole can be a conventional method. Please review FIG. 1 and FIG. 2. The substrate 100 on which the dielectric layer 102 is deposited is covered with a photo-resist layer, and the photo-resist layer is further patterned by Photolithography, such as Exposure and Development. The dielectric layer 102, also named the ONO layer, comprises a bottom oxide (tunnel oxide) layer 104, a silicon nitride (SIN) layer 106 and a top oxide layer 108. Then, the patterned photo-resist (PR) 110 serves as a mask, and the ONO layer is further etched to form the via contact hole 114. The polymer residue remained on the sidewall of photo-resist 110 and the via contact hole 114 come into being the sidewall polymer fence 112.

In order to effectively remove the PR and the sidewall fence polymer without causing any damage to the semiconductor device, several strip processes are developed and experimented by the inventor of the present invention to find out the preferable solution. The strip processes are conducted after the pattern etching process performed either by a pattern etching tool of AMT MPX+/Mxp, or by a pattern etching tool of LAM9400. After each strip process, the sidewall, such as around the via contact hole, is observed to see if any polymer residue is remained, and the flash memory device is further tested to see if the electrical characteristic is stable. The results are summarized in Table 1.

Referring to Table 1, conventional strip process (1), which uses dry strip (O2 plasma) followed by wet strip (CR solution) after the pattern etching process (ONO layer) carried out by AMT MPX+/Mxp etch tool. By applying the conventional strip process (1), slight polymer residue is remained and a little yield loss is caused. However, strip process (2), similar to strip process (1) except that the pattern etching process (ONO layer) is carried out by LAM9400 etch tool, causes serious problem of rich polymer residue and yield loss even up to 40%.

Thus, a series of strip processes are developed for removing the sidewall polymer fence and the PR of the flash memory after patterned by LAM9400 etch tool. The processes and results are described below.

In strip process (3), a wet strip process following the dry strip process is applied. The hydrogen-fluoride (HF) solution, a very strong oxidant, is further used in the wet strip process before CR solution in order to efficiently remove the sidewall polymer fence. However, the HF solution is too aggressive and harmful to the ONO layer, especially to the bare top oxide layer 108. Consequently, the result indicates that GCR (Gate coupling ratio), an index of electrical characteristic stability of the device, is shifted.

Both in strip processes (4) and (5), CR solution are applied twice to remove sidewall polymer fence. However, a dry strip by O2 plasma is applied in strip process (4) but not in strip process (5). The results of strip processes (4) and (5) indicate that the polymer residues still remain on the sidewall even CR solution is applied twice. Also, the results significantly indicate that the dry strip of strip process (4) causes the richer polymer residue than strip process (5). Accordingly, this does prove that the dry strip makes the sidewall polymer fence become hardened and more difficult to be removed.

Since the wet strip process with only CR solution cannot satisfy the requirement of polymer removal, the wet strip processes combining CR solution with another chemical solution are further applied. According to the invention, a wet strip process using SC1 solution and CR solution, which both solutions are admixtures of acidic chemical compounds, is found to effectively remove the sidewall polymer fence and is no harmful to the ONO layer. CR solution, commonly used for removing the sidewall polymer fence, substantially comprises sulfuric acid (H2SO4) and hydrogen peroxide (H2O2). SC1 solution, has been applied in the high temperature approach (approximately 85□˜90□) to remove the polymer, substantially comprises ammonium hydroxide (NH4OH), sulfuric acid (H2SO4) and water (H2O). In the invention, CR solution takes charge of the removal of PR, and SC1 solution takes charge of the removal of sidewall polymer fence basically. Additionally, the key of the invention is that SC1 solution needs to be applied in the low temperature approach for reducing the damage of the ONO layer.

In strip process (6), CR solution is applied before SC1 solution. On the contrary, in strip process (7), SC1 solution is applied before CR solution. The results, as shown in Table 1, indicate that the sidewall polymer fence are completely removed by the wet strip of strip processes (6) and (7); however, there is a GCR (Gate Coupling Ratio) shift issue in strip process (6). This results prove that acidic SC1 solution not only remove sidewall polymer but attacks the ONO layer in the absence of PR, thereby the GCR value represented the electrical characteristic stability of the device is shifted.

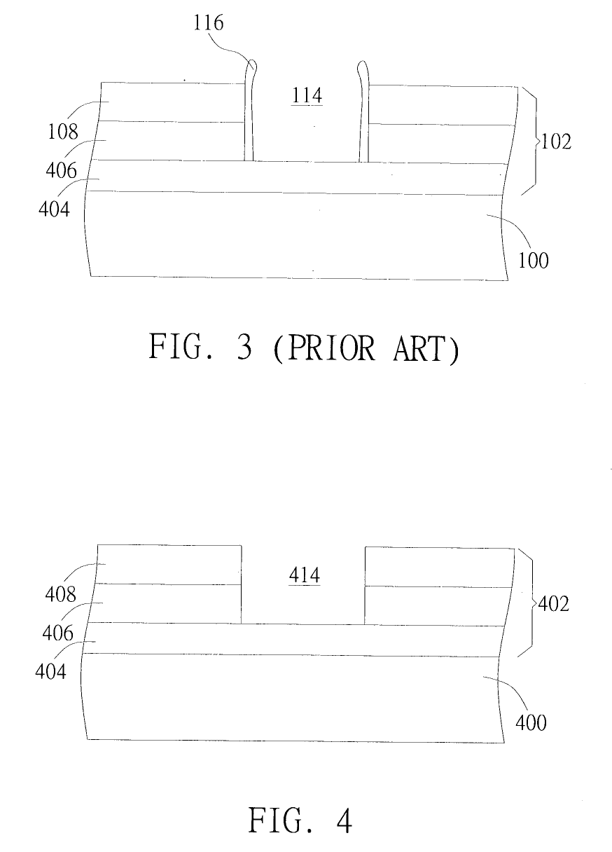

Accordingly, strip process (7) is the preferred solution for effectively removing the sidewall polymer fence and has no harm to the semiconductor device, such as flash memory. The details of strip process of the invention are described below. First, in the presence of photo-resist (PR) 110 (FIG. 2), the sidewall polymer fence 112 (FIG. 2) is completely removes by SC1 solution substantially comprising NH4OH, H2SO4 and H2O, without attacking the ONO layer. Second, the PR 110 is removed by CR solution, substantially comprising H2SO4 and H2O2. Moreover, in consideration of the reduction of the oxide loss and maintenance of the removing effect on the sidewall polymer fence 112, SC1 solution is approached at a low temperature ranged from 30□ to 40□ for 240 to 540 second, approximately. As to the operation condition of CR solution, it is practiced as known in the art. After removing photo-resist and the sidewall polymer fence according to the preferred strip process of the invention, the portion around the via contact hole 414 of the flash memory is illustrated in FIG. 4, which no polymer residue is remained thereon. Also, the device undergoing strip process (7) of the invention does pass the test of device performance, such as electrical characteristic stability, which means that the dielectric layer (ONO layer) 402 of the flash memory of FIG. 4 is not damaged after wet strip process of the invention.

In summary, the preferred method of removing sidewall polymer fence of the dielectric layer of the flash memory, as represented by strip process (7), is the application of a wet strip process using SC1 and CR solutions. Also, SC1 solution is applied first and CR solution comes after in order. The wet strip process according to the present invention not only can easily remove the sidewall polymer fence and the photo-resist, but also well reduces the ONO layer attack and prevents GCR shift. Additionally, strip process of the invention is applicable for a semiconductor device patterned by pattern etching tool of AMT MPX+/Mxp.

While the invention has been described by ways of example and in terms of the preferred embodiment, it is to be understood that the invention is not limited to the disclosed embodiment. To the contrary, it is intended to cover various modifications and similar arrangements and procedures, and the scope of the appended claims therefore should be accorded the broadest interpretation so as to encompass all such modifications and similar arrangements and procedures.

TABLE 1

| | | | Sidewall | |
|---|---|---|---|---|
| ONO | | | Polymer | |
| Etch tool | Strip Process | | Fence | Issue |
| AMT | (1) | Dry strip (O2 | Slightly | Polymer residue |
| MPX+/ | | Plasma) + Wet strip | | |
| Mxp | | (CR process) | | |
| LAM9400 | (2) | Dry strip (O2 | Rich | Polymer residue |
| | | Plasma) + Wet strip | | |
| | | (CR process) | | |
| | (3) | Dry strip (O2 | Free | GCR shift |
| | | Plasma) + Wet strip | | |
| | | (HF + CR) | | |
| | (4) | Wet strip (CR) + Dry | Rich | Polymer residue |
| | | strip (O2 Plasma) + | | |
| | | Wet strip (CR) | | |
| | (5) | Wet strip (CR) + Wet | Slightly | Polymer residue |
| | | strip (CR) | | |
| | (6) | Wet strip (CR + SC1) | Free | GCR shift issue. |
| | (7) | Wet strip (SC1 + CR) | Free | No GCR shift and |
| | | | | polymer residue |
| | | | | issues. |

What is claimed is:

1. A method of removing photo-resist and a polymer residue, wherein the polymer residue is undesired formed while a photo-resist mask is used to pattern at least a layer there beneath, comprising the steps of:
applying SC1 solution, which substantially comprises ammonium hydroxide, sulfuric acid and water, at a temperature ranged from about 30□ to 40□; and
applying CR solution, which substantially comprises sulfuric acid and hydrogen peroxide.

2. The method of removing photo-resist and a polymer residue according to claim 1, wherein the polymer residue is a sidewall polymer fence.

3. The method of removing photo-resist and a polymer residue according to claim 1, wherein the layer beneath the photo-resist layer is a dielectric layer, wherein the dielectric layer comprises a top oxide layer, a silicon nitride layer, and a bottom oxide layer (ONO).

4. The method of removing photo-resist and a polymer residue according to claim 1, wherein at the step of applying SC1 solution, the polymer residue is exposed to SC1 solution for about 240 to 540 seconds.

5. The method of removing photo-resist and a polymer residue according to claim 1, wherein at the step of applying SC1 solution, the polymer residue is exposed to SC1 solution at a temperature of about 35□.

6. A wet strip process of removing photo-resist and a sidewall polymer fence of a dielectric layer comprising SC1 solution and CR solution, and SC1 solution is applied before CR solution, wherein SC1 solution substantially comprising ammonium hydroxide, sulfuric acid and water is applied at a temperature ranged from about 30□ to 40□ for removing the sidewall polymer fence, and CR solution substantially comprising sulfuric acid and hydrogen peroxide is applied for removing photo-resist.

7. The wet strip process according to claim 6, wherein the process is applicable to a flash memory.

8. The wet strip process according to claim 6, wherein SC1 solution is applied at a temperature of about 35□ for removing the sidewall polymer fence.
